(19) United States
(12) Patent Application Publication
(10) Pub. No.: US 2012/0286888 A1
(43) Pub. Date: Nov. 15, 2012

(54) Switched Capacitor Array for Voltage Controlled Oscillator

(75) Inventors: Hsieh-Hung Hsieh, Taipei City (TW); Ming Hsien Tsai, New Taipei City (TW); Tzu-Jin Yeh, Hsin-Chu (TW); Chewn-Pu Jou, Hsin-Chu (TW); Fu-Lung Hsueh, Cranbury, NJ (US)

(73) Assignee: Taiwan Semiconductor Manufacturing Company, Ltd., Hsin-Chu (TW)

(21) Appl. No.: 13/103,592

(22) Filed: May 9, 2011

(51) Int. Cl. H03B 5/12; H03H 11/00

(52) U.S. Cl. 331/117 FE; 327/581

(57) ABSTRACT

A system comprises a voltage controlled oscillator comprising an inductor and a variable capacitor and a switched capacitor array connected in parallel with the variable capacitor. The switched capacitor array further comprises a plurality of capacitor banks wherein a thermometer code is employed to control each capacitor bank. In addition, the switched capacitor array provides N tuning steps for the oscillation frequency of the voltage controlled oscillator when the switched capacitor array is controlled by an n-bit thermometer code.

### BACKGROUND

In radio frequency circuits, such as a receiver or transceiver, a voltage controlled oscillator (VCO) is used as a frequency synthesizer to down-convert or up-convert a radio frequency signal. A VCO may comprise an oscillator designed to be controlled in frequency by a received voltage generated by a VCO control system formed by a frequency divider, a frequency and phase detector, a charge pump and a low pass filter. In the VCO control system, the output of the frequency divider is compared with a reference signal at the frequency and phase detector. The output of the frequency and phase detector is coupled to the low pass filter and further coupled to the oscillator. As a result, the oscillator generates a desired signal in response to the voltage from the low pass filter.

A CMOS VCO may comprise a first inductor L_{P1}, a second inductor L_{P2}, a pair of inversion mode NMOS variable capacitors, a pair of n-channel metal oxide semiconductor (NMOS) transistors M1 and M2 and a bias current source I_{bias}. Both the first inductor L_{P1} and the second inductor L_{P2} may be derived from inductive effects of a square area from a wafer such as a square spiral inductor. The pair of inversion NMOS variable capacitors can be implemented by a pair of NMOS transistors. More particularly, the drain terminals and the source terminals of the pair of NMOS transistors are tied together as a control terminal for fine-tuning the capacitance of the pair of inversion NMOS variable capacitors. By applying a different control voltage at the control terminal, the capacitance of the pair of inversion NMOS variable capacitors changes accordingly. As a result, the oscillation frequency from the L-C tank formed by the first inductor L_{P1}, the second inductor L_{P2} and the pair of inversion mode NMOS variable capacitors can be tuned over a range. For example, when the control voltage varies from zero volts to one volts, the oscillation frequency from the L-C tank can be tuned over 4 GHz from 50 GHz to 54 GHz.

In order to further fine-tune the oscillation frequency of the L-C tank, an additional switched capacitor array may be connected with the pair of inversion mode NMOS variable capacitor in parallel. By switching on or off a capacitor bank of the switched capacitor array, a fine tuning step of the L-C tank can be achieved.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a schematic diagram of a cross-coupled voltage controlled oscillator in accordance with an embodiment;

FIG. 2 illustrates a schematic diagram of an n-bit switched capacitor array in accordance with an embodiment;

FIG. 3 illustrates a schematic diagram of a capacitor bank in accordance with an embodiment;

FIG. 4 illustrates in detail a schematic diagram of a 7-bit switched capacitor array in accordance with an embodiment;

FIG. 5 illustrates in detail the operation of the thermometer code controlled 7-bit switched capacitor array shown in FIG. 4; and

FIG. 6 illustrates the experimental results based upon the thermometer code controlled 7-bit switched capacitor array shown in FIG. 4.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, a thermometer code controlled switched capacitor array for fine-tuning a cross-coupled voltage controlled oscillator (VCO). The invention may also be applied, however, to a variety of VCO circuits.

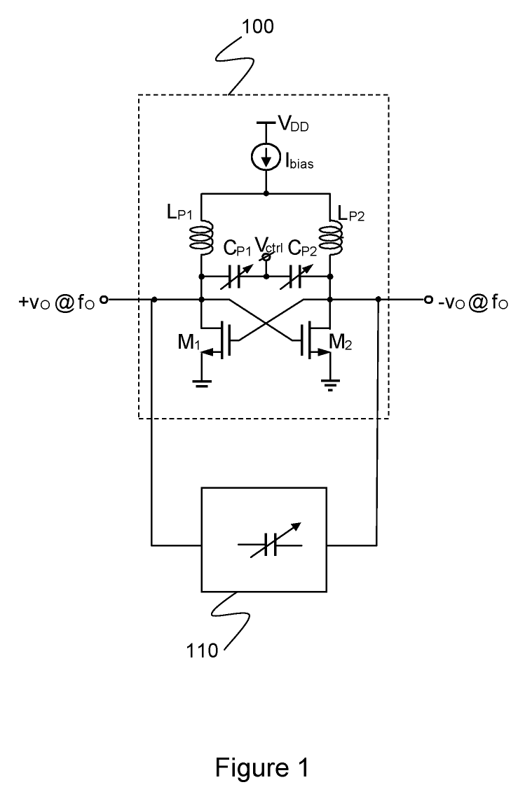

Referring initially to FIG. 1, a schematic diagram of a cross-coupled voltage controlled oscillator is illustrated in accordance with an embodiment. The cross-coupled voltage controlled oscillator 100 comprises a first inductor L_{P1}, a second inductor L_{P2}, a first variable capacitor C_{P1}, a second variable capacitor C_{P2} a pair of n-channel metal oxide semiconductor (NMOS) transistors M1 and M2 and a bias current source I_{bias}. Both the first inductor L_{P1} and the second inductor L_{P2} are coupled to a voltage potential VDD via the bias current source I_{bias} at one terminal. The first inductor L_{P1} has the other terminal coupled to the first variable capacitor C_{P1}. Likewise, the second inductor L_{P2} has the other terminal coupled to the second variable capacitor C_{P2}.

Furthermore, the first variable capacitor C_{P1}, and the second variable capacitor C_{P2} are connected in series and the junction point between the first variable capacitor C_{P1}, and the second variable capacitor C_{P2} is used as a voltage control terminal V_{ctrl}. As known in the art, by applying different voltages at the voltage control terminal, the capacitance of each variable capacitor (e.g., the first variable capacitor C_{P1}) changes accordingly. It should be noted that the inductors L_{P1}, and L_{P2} may be derived from inductive effects of a square area from a wafer such as a square spiral inductor. Both variable capacitors C_{P1} and C_{P2} may be derived from a pair of NMOS transistors operating as a pair of inversion NMOS variable capacitors by connecting each NMOS transistor's drain and source together. The operation principle of an inversion NMOS variable capacitor is well-known in the art, and thus is not discussed herein.

The L-C tank formed by the first inductor L_{P1}, the second inductor L_{P2}, the first variable capacitor C_{P1} and the second variable capacitor C_{P2} are further coupled to a pair of NMOS transistors M1 and M2. The NMOS transistor M1 and the NMOS transistor M2 are cross-coupled to opposite terminals. More particularly, the gate of the NMOS transistor M1 is coupled to the drain of the NMOS transistor M2 and the gate of the NMOS transistor M2 is coupled to the drain of the NMOS transistor M1. The sources of both NMOS transistor M1 and M2 are connected together and coupled to ground. As known in the art, the cross-coupled VCO 100 is capable of having a wider tuning range by fine-tuning the value of the variable capacitors C_{P1} and C_{P2} by adjusting the voltage at V_{ctrl}. However, in order to further fine-tune the oscillation frequency of the cross-coupled VCO 100, a switched capacitor array 110 is needed to provide extra fine tuning steps.

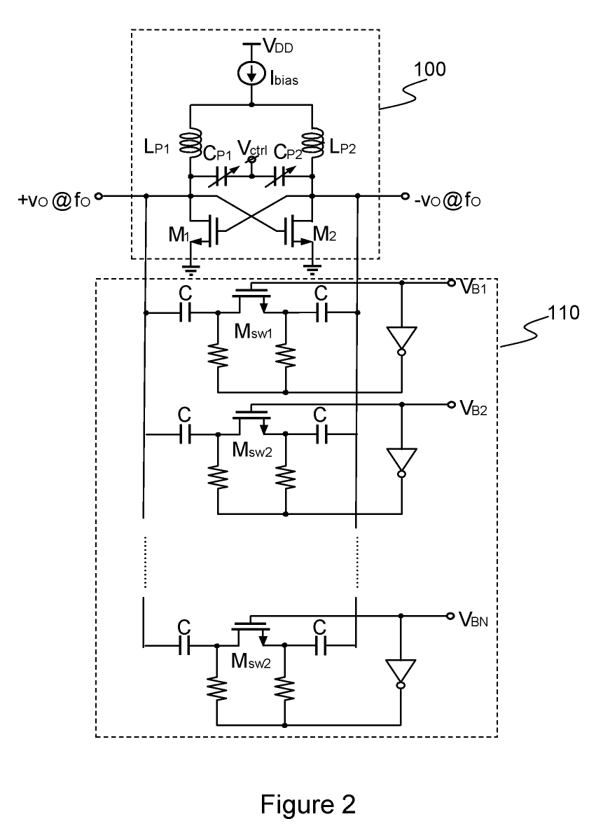

FIG. 2 illustrates a schematic diagram of an n-bit switched capacitor array in accordance with an embodiment. As illustrated in FIG. 2, the n-bit switched capacitor array is connected in parallel with the variable capacitors of the cross-coupled VCO 100. There may be n control bits carrying control signals coupled to each corresponding capacitor bank. It should be noted that the integer n is equal to or greater than 2. As shown in FIG. 2, each capacitor bank may have the same structure. All n capacitor banks are connected in parallel to form the switched capacitor array 110. In response to the logic state of the control signal coupled to a capacitor bank, the capacitor bank is either connected with the variable capacitors C_{P1} and C_{P2} in parallel or removed from the L-C tank of the cross-coupled VCO 100. As a result, at a particular control voltage applied at V_{ctrl}, there are at least n extra tuning steps available by enabling the n-bit switched capacitor array 110 connected with the L-C tank in parallel.

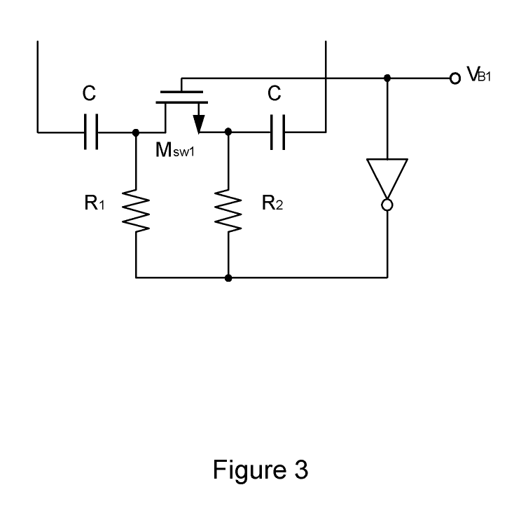

FIG. 3 illustrates a schematic diagram of a capacitor bank in accordance with an embodiment. As described above with respect to FIG. 2, each capacitor bank in the switched capacitor array 110 has the same structure. Therefore, a capacitor bank (e.g., the first capacitor bank) is used to illustrate the operation principle of the capacitor bank. The capacitor bank may comprise two identical capacitors connected in series via a switch Msw1. The switch Msw1 may be an NMOS transistor having a drain coupled to one capacitor, a source coupled to the other capacitor and a gate coupled to a control signal (e.g., the first control bit V_{P1}). The switch Msw1 is floating from ground. In order to properly bias the switch Msw1, two bias resistors R1, R2 and an inverter are employed to form a bias circuit for driving the switch Msw1. More particularly, when V_{B1} is at a logic high state such as VDD, the output of the inverter is at zero volts. Through the bias resistor R2, the source of the switch Msw1 is set to zero volts too. As a result, the gate-to-source voltage of the switch Msw1 is VDD, which is higher than the threshold of the switch Msw1 so that the switch Msw1 is guaranteed to be turned on.

On the other hand, when the control signal V_{B1} is at a logic low state, the output of the inverter generates a logic high state such as VDD. Through the bias resistor R2, the source of the switch Msw1 is set to VDD. As a result, a negative voltage −VDD is applied to the gate and the source of the switch Msw1. As known in the art, a negative gate-to-source voltage of the switch Msw1 can firmly turn off the switch Msw1. An advantageous feature of having the capacitor bank shown in FIG. 3 is that a capacitor can be reliably switched on or off from the L-C tank of the cross-coupled VCO 100 so that the oscillator can precisely generate a specified high frequency signal according to an n-bit control signal.

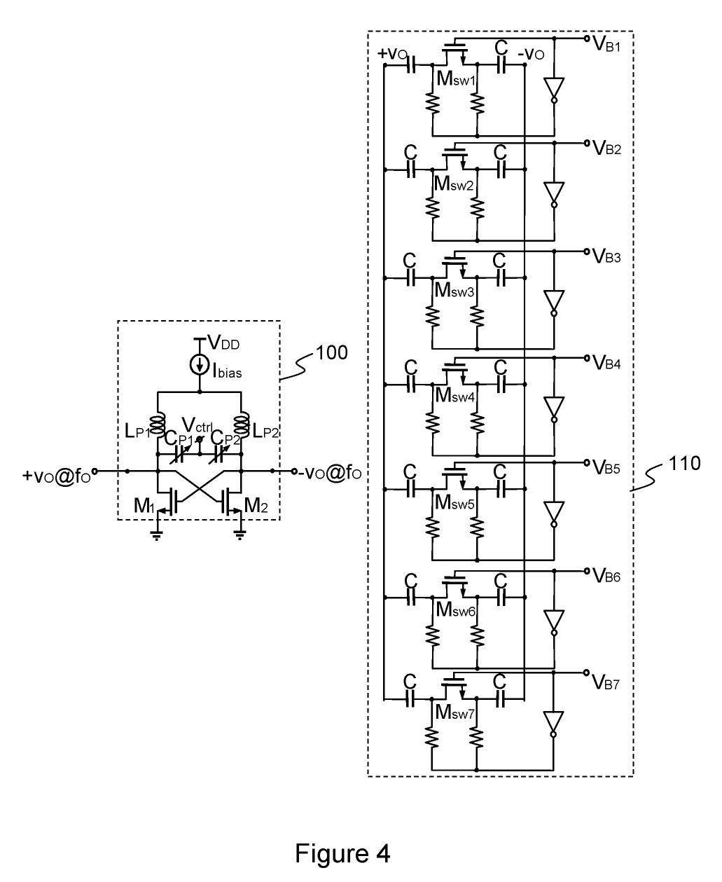

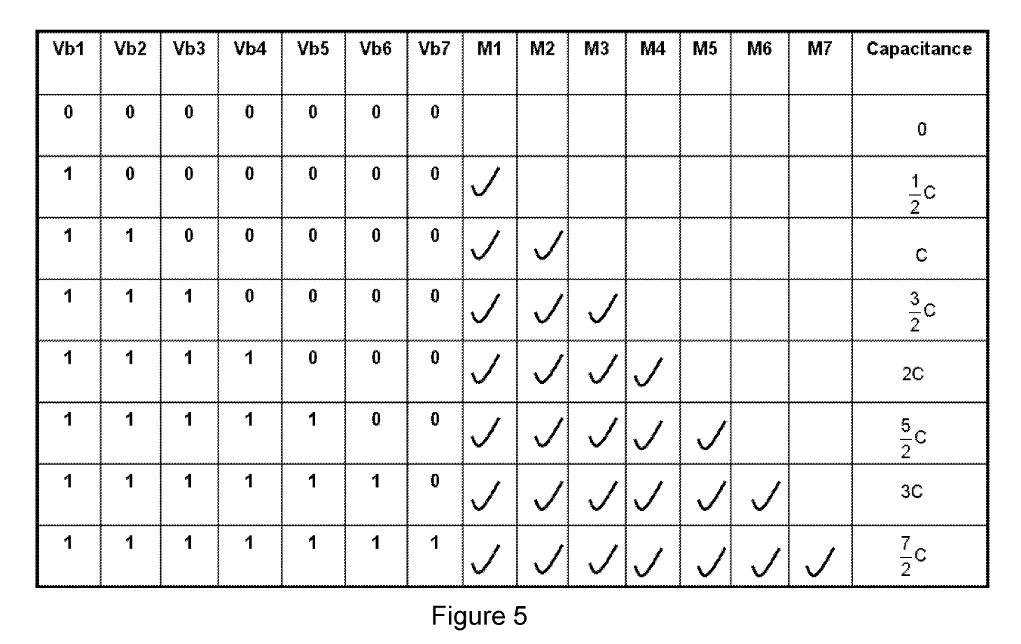

FIG. 4 illustrates in detail a schematic diagram of a 7-bit switched capacitor array in accordance with an embodiment. The switched capacitor array 110 comprises seven capacitor banks. All seven capacitor banks share the same structure, which has been described in detail with respect to FIG. 3. The operation of the switched capacitor array 110 is controlled by a 7-bit thermometer code. As known in the art, a thermometer code employs a plurality of equally weighted elements. That is, each capacitor bank controlled by a thermometer code contains an equal capacitor value. For example, in order to achieve a thermometer code value of “2”, the first two inputs (e.g., V_{B1} and V_{B2}) of the thermometer code are enabled. As a result, the first two capacitor banks are connected with the L-C tank in parallel and each capacitor bank contributes an equal capacitor value to the variable capacitor of the L-C tank. The detailed operation of the switched capacitor array 110 controlled by a 7-bit thermometer code will be discussed below with respect to FIG. 5.

FIG. 5 illustrates in detail the operation of the thermometer code controlled 7-bit switched capacitor array shown in FIG. 4. For example, when the 7-bit thermometer code (V_{B1}, V_{B2}, V_{B3}, V_{B4}, V_{B5}, V_{B6}, V_{B7}) is “0000000”, each switch of seven capacitor banks is turned off. As a result, no extra capacitors are added into the L-C tank. On the other hand, when the 7-bit thermometer code is “1111111”, each switch of seven capacitor banks is turned on. As a consequence, each capacitor bank contributes

$$\frac{C}{2}$$

into the L-C tank. As shown in the table, totally a capacitance value of

$$\frac{7 C}{2}$$

is added into the L-C tank. When the 7-bit thermometer code is in between “0000000” and “1111111,” various switches are turned on or off as illustratively marked in FIG. 5.

According to the operation principle of thermometer code, an equal amount of capacitance is added when the thermometer code is increased by “1”. That is, each capacitor bank can have identical layout, which may simplify the design of the switched capacitor array 110. Furthermore, in comparison with a binary code controlled switched capacitor array, which may need a capacitance value of 2^{N}C for the capacitor bank controlled by the n^{th} bit, the equal amount of capacitance for each capacitor bank further improves the performance of switched capacitors at a frequency in the range more than 1 GHz. As known in the art, a large capacitor performs poorly in quality factor at an extra high frequency such as 50 GHz. Therefore, a thermometer code controlled switched capacitor array may perform better than the counterpart controlled by a binary code because at a control bit such as the n^{th} control bit it needs a capacitance value equal to C rather than 2^{N}C.

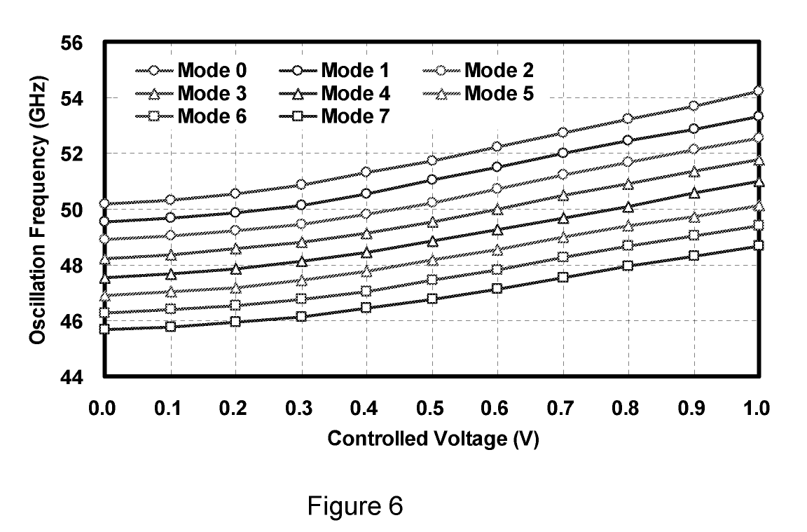

FIG. 6 illustrates the experimental results based upon the thermometer code controlled 7-bit switched capacitor array 110 shown in FIG. 4. The horizontal axis of FIG. 6 represents the control voltage at V_{ctrl}. The vertical axis of FIG. 6 represents the oscillation frequency generated by the cross-coupled VCO 100. There are eight curves corresponding to eight different modes set by the 7-bit thermometer code (not shown but illustrated in FIG. 5). As shown in FIG. 6, at a particular mode, when the control voltage increases from 0 V to 1.0V, the oscillation frequency of the cross-coupled VCO 100 increases accordingly in an approximately linear relationship. For example, at Mode 0, the oscillation frequency may vary from 50 GHz to 54 GHz when the control voltage changes from 0V to 1.0V. On the other hand, the oscillation frequency can be further adjusted by changing the operation mode from Mode 0 to Mode 7 by giving different thermometer code values. For example, at a fixed control voltage such as V_{ctrl}=0.3V, the oscillation frequency has a tuning range from 46 GHz to 51 GHz by changing from Mode 7 to Mode 0.

Although embodiments of the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A system comprising:
a voltage controlled oscillator comprising an inductor and a variable capacitor; and
a switched capacitor array connected in parallel with the variable capacitor comprising:
a plurality of capacitor banks wherein a thermometer code is employed to control each capacitor bank.

2. The system of claim 1, where the capacitor bank comprises:
a first capacitor;
a second capacitor connected in series with the first capacitor via a switch, wherein the switch has a gate coupled to a bit of the thermometer code;
an inverter having an input coupled to the bit of the thermometer code;
a first bias resistor connected between a drain of the switch and an output of the inverter; and
a second bias resistor connected between a source of the switch and the output of the inverter.

3. The system of claim 2, wherein an output of the inverter is coupled to the first bias resistor and the second bias resistor and the inverter is configured such that:
a positive voltage is across from the gate to the source of the switch when a logic high state is applied at the bit of the thermometer code; and
a negative voltage is across from the gate to the source of the switch when a logic low state is applied at the bit of the thermometer code.

4. The system of claim 1, wherein the voltage controlled oscillator is a cross-coupled oscillator comprising:
a L-C bank formed by a first inductor, a second inductor, a first capacitor and a second capacitor;
a cross-coupled transistor pair wherein a first transistor has a gate coupled to a drain of a second transistor and the second transistor has a gate coupled to a drain of the first transistor; and
a bias current source coupled between the cross-coupled transistor pair and a voltage potential.

5. The system of claim 4, wherein the first capacitor and the second capacitor are formed by a pair of NMOS transistors having a drain terminal connected to a source terminal.

6. The system of claim 4, wherein the first capacitor and the second capacitor have a capacitance value varying in response to a control voltage applied to a control terminal located at a junction point between the first capacitor and the second capacitor.

7. The system of claim 6, wherein the control voltage varies from zero volts to the voltage potential.

8. A switched capacitor array comprising:
a capacitor bank comprising:
a first capacitor;
a second capacitor connected in series with the first capacitor via a switch, wherein the switch has a gate coupled to a bit of a thermometer code;
an inverter having an input coupled to the bit of the thermometer code;
a first bias resistor connected between a drain of the switch and an output of the inverter; and
a second bias resistor connected between a source of the switch and the output of the inverter.

9. The switched capacitor array of claim 8, wherein the first capacitor has a capacitance value equal to that of the second capacitor.

10. The switched capacitor array of claim 8, wherein the first capacitor and the second capacitor are connected in parallel with a variable capacitor of an L-C bank when a logic high state is applied to the bit of the thermometer code coupled to the gate of the switch.

11. The switched capacitor array of claim 8, wherein a bias circuit formed by the inverter, the first bias resistor and the second bias resistor is configured such that:
a positive voltage is across from the gate to the source of the switch when a logic high state is applied at the bit of the thermometer code; and
a negative voltage is across from the gate to the source of the switch when a logic low state is applied at the bit of the thermometer code.

12. The switched capacitor array of claim 8, the switch is an NMOS transistor.

13. The switched capacitor array of claim 8, wherein the switched capacitor array comprises N capacitor banks when the switched capacitor array is controlled by an n-bit thermometer code.

14. The switched capacitor array of claim 8, wherein the switched capacitor array provides N tuning steps when the switched capacitor array is controlled by an n-bit thermometer code.

15. A method comprising:
connecting a switched capacitor array in parallel with a variable capacitor of an L-C tank of a voltage controlled oscillator;
receiving an n-bit thermometer code at the switched capacitor array comprising N capacitor banks, wherein each capacitor bank is controlled by one bit of the n-bit thermometer code; and
turning on or off a switch connected in series with a first capacitor and a second capacitor of a capacitor bank in accordance with a corresponding bit of the n-bit thermometer code.

16. The method of claim 15, further comprising:
providing a positive gate-to-source voltage when a logic high state is applied at the bit of the thermometer code; and
providing a negative gate-to-source voltage when a logic low state is applied at the bit of the thermometer code.

17. The method of claim 15, further comprising fine-tuning the voltage controlled oscillator in accordance with a selective thermometer code.

18. The method of claim 15, further comprising tuning the voltage controlled oscillator in accordance with a control voltage.

19. The method of claim 15, further comprising:
turning on the switch connected in series with the first capacitor and the second capacitor of the capacitor bank when the corresponding bit of the n-bit thermometer code is at a logic high state; and
turning off the switch connected in series with the first capacitor and the second capacitor of the capacitor bank when the corresponding bit of the n-bit thermometer code is at a logic low state.

20. The method of claim 15, further comprising:
providing a bias circuit formed by an inverter, a first bias resistor and a second bias resistor;
providing a positive voltage from a gate terminal to a source terminal of the switch when a logic high state is applied at the bit of the thermometer code; and
providing a negative voltage from the gate terminal to the source terminal of the switch when a logic low state is applied at the bit of the thermometer code.
